(19) United States
(12) Patent Application Publication
(10) Pub. No.: US 2025/0174573 A1
(43) Pub. Date: May 29, 2025

(54) PACKAGED SEMICONDUCTOR CHIPS HAVING PROTECTED IDENTIFICATION MARKS THEREIN

(71) Applicant: Samsung Electronics Co., Ltd., Suwon-si (KR)

(72) Inventors: Yeongkwon Ko, Suwon-si (KR); Soyeon Kwon, Suwon-si (KR); Seunghun Shin, Suwon-si (KR); Teak Hoon Lee, Suwon-si (KR)

(21) Appl. No.: 18/817,592

(22) Filed: Aug. 28, 2024

(30) Foreign Application Priority Data
Nov. 24, 2023 (KR) 10-2023-0165408

(51) Int. Cl. H01L 23/544; H01L 23/29; H01L 23/31; H01L 25/065; H01L 25/10; H10B 80/00

(52) U.S. Cl. CPC H01L 23/544; H01L 23/291; H01L 23/293; H01L 23/3135; H01L 25/0657; H01L 25/105; H10B 80/00; H01L 2223/54433; H01L 2225/06513; H01L 2225/06541; H01L 2225/1023; H01L 2225/1058

(57) ABSTRACT

A semiconductor chip includes a semiconductor substrate having an identification mark extending adjacent a first surface thereof, and a light transmitting layer, which extends on the first surface of the semiconductor substrate and covers the identification mark. A connection pad is provided, which extends on a second surface of the semiconductor substrate extending opposite the first surface of the semiconductor substrate. A light transmittance of the light transmitting layer with respect to light having a wavelength in a range from 355 nm to 980 nm is 90% or more.

### REFERENCE TO PRIORITY APPLICATION

This application claims priority under 35 U.S.C. 119 to Korean Patent Application No. 10-2023-0165408, filed Nov. 24, 2023, the disclosure of which is hereby incorporated herein by reference.

### BACKGROUND

The present disclosure relates to packaged semiconductor chips.

In the semiconductor industry, for the purpose of tracking information on wafers, semiconductor chips, semiconductor packages, etc., the surface of a wafer or substrate may be processed with a UV laser to form an identification mark. During laser surface processing, dust may be generated that causes a semiconductor chip to become contaminated and such contamination may decrease chip yield.

Therefore, new semiconductor chips and semiconductor packages that may prevent product contamination and yield reduction due to dust generated during laser processing are required.

### SUMMARY

The present disclosure highlights a semiconductor chip and a semiconductor package that are capable of preventing product contamination due to dust generation during laser processing to form an identification mark.

A semiconductor chip may include a semiconductor substrate having an identification mark located on a first surface thereof, a light transmitting layer extending on the first surface of the semiconductor substrate and covering the identification mark, and a connection pad extending on a second surface of the semiconductor substrate, which is opposite the first surface of the semiconductor substrate.

A semiconductor package may include a first semiconductor chip having a semiconductor substrate therein with an identification mark extending adjacent a first surface of the substrate, and a light transmitting layer extending on the first surface of the semiconductor substrate to cover the identification mark. A molding material, which is molded to the first semiconductor chip, may also be provided. The light transmitting layer may be exposed to a first surface of the molding material.

A semiconductor package may include a semiconductor chip, and a molding material that is molded to the semiconductor chip and includes an identification mark; the identification mark may be located inside from a surface of the molding material.

According to another aspect of the present disclosure, a semiconductor chip and a semiconductor package, which is capable of preventing product contamination due to dust generation during laser processing to form an identification mark, may be provided.

### BRIEF DESCRIPTION OF THE DRAWINGS

FIG. 1 is a cross-sectional view of a semiconductor chip having an identification mark located on a chip surface.

FIG. 2 is a cross-sectional view of a semiconductor chip having an identification mark according to the present disclosure.

FIG. 3 is a perspective view of a semiconductor chip shown in FIG. 2.

FIG. 4 shows absorption rates depending on wavelength of some materials including silicon oxide.

FIG. 5 shows transmittance depending on wavelengths of some materials.

FIG. 6 is a cross-sectional view of an exemplary semiconductor package including a semiconductor chip having an identification mark according to the present disclosure.

FIG. 7 is a cross-sectional view of another exemplary semiconductor package including a semiconductor chip having an identification mark according to the present disclosure.

FIG. 8 is a cross-sectional view of a still another exemplary semiconductor package including a semiconductor chip having an identification mark according to the present disclosure.

FIG. 9 is a cross-sectional view of a still another exemplary semiconductor package including a semiconductor chip having an identification mark according to the present disclosure.

FIG. 10 is a cross-sectional view of a still another exemplary semiconductor package including a semiconductor chip having an identification mark according to the present disclosure.

FIG. 11 is a cross-sectional view of an exemplary semiconductor package including a molding material having an identification mark of the present disclosure.

FIG. 12 is a cross-sectional view of another exemplary semiconductor package including a molding material having an identification mark of the present disclosure.

### DETAILED DESCRIPTION OF EMBODIMENTS

The present disclosure will be described more fully hereinafter with reference to the accompanying drawings, in which exemplary embodiments of the disclosure are shown. As those skilled in the art would realize, the described embodiments may be modified in various different ways, all without departing from the spirit or scope of the present disclosure. The drawings and description are to be regarded as illustrative in nature and not restrictive. Like reference numerals designate like elements throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., may be exaggerated for clarity.

Throughout this specification and the claims that follow, when it is described that an element is “coupled/connected” to another element, the element may be “directly coupled/connected” to the other element or “indirectly coupled/connected” to the other element through a third element. In a similar sense, this includes being “physically connected” as well as being “electrically connected”. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements. Further, throughout the specification, the phrase “in a plan view” means when an object portion is viewed from above, and the phrase “in a cross-sectional view” means when a cross-section taken by vertically cutting an object portion is viewed from the side.

In addition, throughout the specification, sequential numbers such as first and second are used to distinguish a certain component from another component that is the same or similar to the certain component, and are not necessarily intended to refer to a specific component. Accordingly, a component referred to as a first component in a particular portion of the specification may be referred to as a second component in another portion of the specification. And, a singular reference to a component includes references to a plurality of these components, unless specifically stated to the contrary. For example, “an insulation layer” may be used to mean not only one insulation layer but also a plurality of insulation layers such as two, three, or more insulation layers.

References to one (or first) surface and the other (or second) surface are intended to distinguish different surfaces from each other, and are not necessarily intended to limit it to a specific surface. Therefore, a surface referred to as one (or first) surface in a specific portion of the specification may be referred to as the other (or second) surface in another portion of the specification.

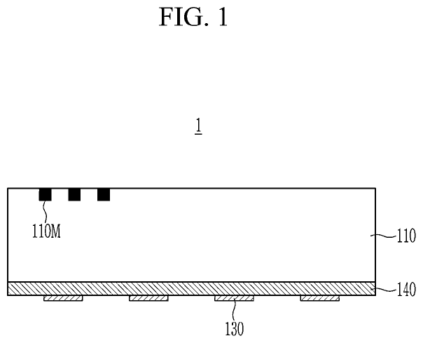

FIG. 1 is a cross-sectional view of a semiconductor chip having an identification mark located on a chip surface. A semiconductor chip 1 may include a semiconductor substrate 110 having an identification mark 110M located on the first surface, and a connection pad 130 and a circuit structure 140 disposed on the second surface, which is an opposite surface of the first surface of the semiconductor substrate 110. The semiconductor substrate 110 may include silicon (Si). Alternatively, the semiconductor substrate 110 may include a semiconductor element or semiconductor compound such as germanium (Ge), silicon germanium (SiGe), gallium arsenide (GaAs), silicon carbide (SiC), indium arsenide (InAs).

The connection pad 130 is a component for electrically connecting the semiconductor chip 1 to another component, and may be formed of a conductive material such as copper (Cu) and aluminum (Al). The circuit structure 140 may include a plurality of individual “active” devices (e.g., transistors), internal circuits, interlayer insulating layers, or the like formed through a front end of line (FEOL) process and a back end of line (BEOL) process. The connection pad 130 may be electrically connected to the circuit structure 140. In the technical field to which the present disclosure belongs, the surface having the circuit structure 140 and the connection pad 130 thereon may be referred to as an active surface of the substrate 110, and an opposite surface of the active surface may be referred to as an inactive surface of the substrate.

The identification mark 110M may be formed on the inactive surface of the semiconductor substrate 110. The identification mark 110M may be formed by processing the surface of the semiconductor substrate 110 with laser, e.g., for the purpose of tracking information (e.g., Lot ID or the like) of the semiconductor chip, and for example, may be in the form of vision recognizable 2-dimensional barcode, characters, numbers, or the like. However, when the surface of the semiconductor substrate 110 is conventionally processed with a laser, dust may be generated to contaminate the product, possibly causing deterioration of yield. Therefore, it would be advantageous to have a new semiconductor chip and semiconductor package capable of preventing contamination of the product and deterioration of yield due to dust generated during laser processing.

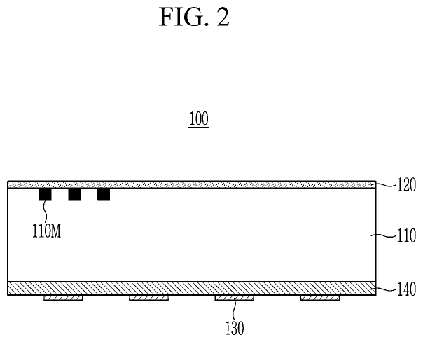

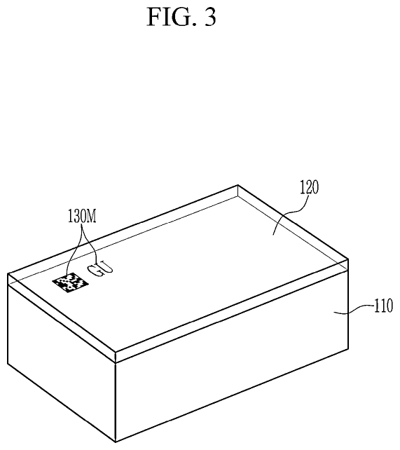

FIG. 2 is a cross-sectional view of a semiconductor chip having an identification mark according to the present disclosure, and FIG. 3 is a perspective view of a semiconductor chip shown in FIG. 2. The semiconductor chip 100 according to the present disclosure may include the semiconductor substrate 110 having the identification mark 110M located on a first surface, a light transmitting layer 120 disposed on the first surface of the semiconductor substrate 110 to cover the identification mark 110M, and the connection pad 130 and the circuit structure 140 disposed on the second surface of the semiconductor substrate 110. In some embodiments, the identification mark 110M may be formed by providing the light transmitting layer 120 to be capable of transmitting laser onto the first surface of the semiconductor substrate 110, and irradiating laser onto the light transmitting layer 120. Advantageously, because the laser processing is performed on the surface of the semiconductor substrate 110 covered by the light transmitting layer 120, the problem of contamination of the product due to dust generated during laser processing may be prevented.

As a material of the light transmitting layer 120, a material having a low light absorption rate and high light transmittance with respect to wavelength range of a laser light capable of surface processing the semiconductor substrate 110 may be used. The light transmitting layer 120 may include, for example, silicon oxide. The present inventors confirmed through experiments that an identification mark may be formed on a silicon substrate by forming a silicon dioxide (SiO₂) layer on the silicon substrate through a deposition process and by irradiating a UV laser having a wavelength of 355 nm. However, a material that may be used as the light transmitting layer 120 is not limited to silicon oxide, and a person of an ordinary skill in the art may select a material having a low light absorption rate and high light transmittance with respect to a wavelength range of a laser light used for surface processing of semiconductor substrate and use it as a material of the light transmitting layer 120.

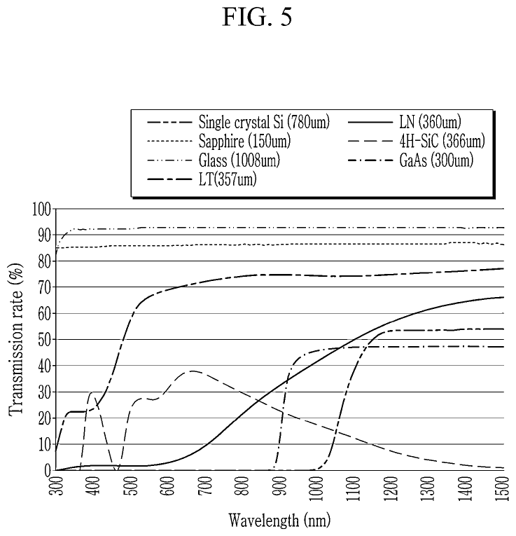

Referring to FIG. 5, silicon, which is a representative material of the semiconductor substrate 110, may be difficult to be processed since light transmittance rapidly increases at a wavelength of 980 nm or more. Therefore, it may be preferable that a material having high light transmittance at a wavelength of 980 nm or less at which processing of the semiconductor substrate 110 is enabled may be used as the light transmitting layer 120. In addition, the processing of the semiconductor substrate 110 is not limited thereto, and may be performed with a UV laser having a wavelength of 355 nm or more. Therefore, the light transmittance of the light transmitting layer 120 in the wavelength from 355 nm to 980 nm may be 90% or more. Referring to FIG. 5, it may be seen that silica (SiO₂) glass shows a high light transmittance of 90% or more with respect to a light having a wavelength range of 355 nm or more and 980 nm or less, and is suitable as a material of the light transmitting layer 120.

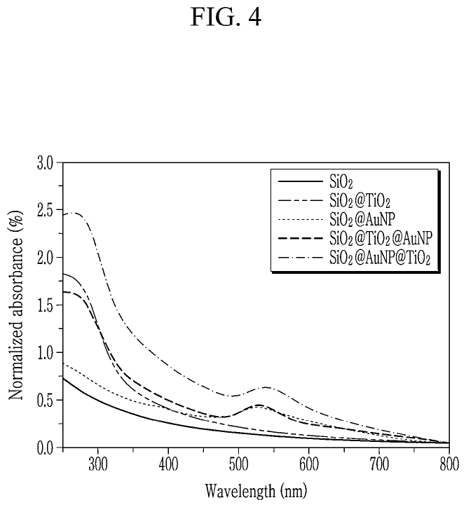

On the other hand, the light absorption rate of the light transmitting layer 120 at the wavelength used for the laser processing may be low. For example, a light absorption rate of the light transmitting layer 120 with respect to the light having a wavelength range of 355 nm or more and 980 nm or less may be less than 15%, less than 10%, less than 5%, less than 3% or less than 1.5%, and preferably less than 1%. Referring to FIG. 4, it may be seen that the light absorption rate of silicon dioxide (SiO₂) with respect to the light having a wavelength range of 355 nm or more and 980 nm or less is less than 1%, and is suitable as a material of the light transmitting layer 120.

The light transmitting layer 120 may further include at least one of titanium dioxide (TiO₂) and Au nanoparticle (AuNP). For example, the light transmitting layer 120 may include a material in a core-shell structure in which titanium dioxide (TiO₂) and/or Au nanoparticles (AuNP) are as attached as an additional layer on a surface of silicon dioxide (SiO₂) particles.

In FIG. 4, it may be seen that, with respect to all of core shell particles in which titanium dioxides (TiO₂) are attached to silicon dioxide (SiO₂) particles, core shell particles in which Au nanoparticles (AuNP) are attached to silicon dioxide (SiO₂) particles, core shell particles in which titanium dioxides (TiO₂) and Au nanoparticles (AuNP) are sequentially attached to silicon dioxide (SiO₂) particles, and core shell particles in which Au nanoparticles (AuNP) and titanium dioxides (TiO₂) are sequentially attached to silicon dioxide (SiO₂) particles, the light absorption rate with respect to the light having a wavelength range of 355 nm or more and 980 nm or less is less than 1.5%.

A forming method of the light transmitting layer 120 is not particularly limited, and may be formed, for example, through a deposition process of an oxide layer such as silicon dioxide (SiO₂) or an oxidation process of the semiconductor substrate 110. A thickness 120t of the light transmitting layer 120 may be 7 μm or more and 70 μm or less. When the light transmitting layer 120 is above 70 μm, it may be difficult to secure visibility of the identification mark 110M. In addition, in order to secure visibility of the identification mark 110M, the light transmitting layer 120 may be transparent or translucent. The light absorption rate of the semiconductor substrate 110 with respect to the light having a wavelength range of 355 nm or more and 980 nm or less may be at least 15%. When the light absorption rate of the semiconductor substrate 110 is lower than 15%, it may be difficult to process with laser.

A region where the identification mark 110M of the semiconductor substrate 110 is located may be modified by the laser processing, and may include amorphous silicon. On the other hand, other regions that are not processed with laser (regions where the identification mark 110M is not located) may include single crystalline silicon.

Other descriptions of the semiconductor substrate 110, the connection pad 130 and the circuit structure 140 is the same as described above, and detailed description thereof will be omitted. Meanwhile, the application of the present disclosure is not limited to the circuit structure 140 and the connection pad 130, and may be applied to a semiconductor wafer. An identification mark may be formed on a semiconductor wafer by disposing the light transmitting layer 120 according to the present disclosure on the semiconductor wafer and then by processing it with laser. Thus, it may be understood that the description of the semiconductor substrate 110 according to the present disclosure may be equally applied to the semiconductor wafer.

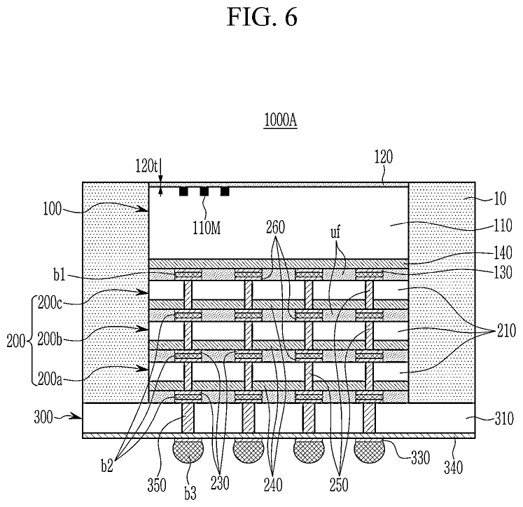

FIG. 6 is a cross-sectional view of an exemplary semiconductor package including a semiconductor chip having an identification mark according to the present disclosure. Referring to the drawings, a semiconductor package 1000A may include a first semiconductor chip 100, one or more second semiconductor chips 200, a third semiconductor chip 300 and a molding material 10. The first semiconductor chip 100 may be disposed on the second semiconductor chip 200, and may be disposed on a second semiconductor chip 200c located uppermost among a plurality of second semiconductor chips 200.

The first semiconductor chip 100 may be a semiconductor chip according to the present disclosure, and may include the semiconductor substrate 110 having the identification mark 110M located on the first surface, the light transmitting layer 120 disposed on the first surface of the semiconductor substrate 110 to cover the identification mark 110M, and the connection pad 130 and the circuit structure 140 disposed on the second surface of the semiconductor substrate 110.

The light transmitting layer 120 may be exposed to a first surface of the molding material 10, in order to secure visibility of the identification mark 110M. The first surface of the light transmitting layer 120 may be coplanar with the first surface of the molding material 10, but it is not limited thereto, and for example, may protrude onto the first surface of the molding material 10. If necessary, the first surface of the molding material 10 may protrude onto the first surface of the light transmitting layer 120.

The connection pad 130 of the first semiconductor chip 100 may electrically connect the first semiconductor chip 100 to the second semiconductor chip 200c. The type of the first semiconductor chip 100 is not particularly limited, and may be a memory chip such as a high bandwidth memory (HBM) or a dummy chip disposed on the second semiconductor chip 200. Other descriptions of each configuration of the first semiconductor chip 100 is the same as described above, and detailed description thereof will be omitted.

The second semiconductor chip 200 may include a plurality of second semiconductor chips 200a, 200b, and 200c. The number of the second semiconductor chip 200 may be more or less than shown in the drawings. The second semiconductor chip 200 may include a semiconductor substrate 210, a first connection pad 230, a circuit structure 240, a second connection pad 250 and a through-via 260. The semiconductor substrate 210 may include silicon (Si), and for example, a silicon substrate. Alternatively, the semiconductor substrate 210 may include a semiconductor element or compound such as germanium (Ge), silicon germanium (SiGe), gallium arsenide (GaAs), silicon carbide (SiC), indium arsenide (InAs).

The first connection pad 230 and the second connection pad 250 are components for electrically connecting the second semiconductor chip 200 to another component, respectively, and may be formed of a conductive material such as copper (Cu) and aluminum (Al). For example, the first connection pad 230 may electrically connect one second semiconductor chip 200 to another second semiconductor chip 200 or the third semiconductor chip 300, and the second connection pad 250 may electrically connect one second semiconductor chip 200 to another the second semiconductor chip 200 or the first semiconductor chip 100.

The first connection pad 230 and the second connection pad 250 may be disposed on the first surface and the second surface of the second semiconductor chip 200 that are opposite to each other, respectively, and may be electrically connected to each other through the through-via 260. The circuit structure 240 may include a plurality of individual devices (e.g., transistors), internal circuits, interlayer insulating layers, or the like formed through a front end of line (FEOL) process and a back end of line (BEOL) process. The through-via 260 may penetrate the semiconductor substrate 210 to may electrically connect the first connection pad 230 and the second connection pad 250, and may also be electrically connected to the circuit structure 240. In addition, the through-via 260 may electrically connect one second semiconductor chip 200 to the first semiconductor chip 100 and/or another the second semiconductor chip 200.

As a forming method of the through-via 260, via first, via middle, and via last methods may be used without limitation, and all or some of the circuit structure 240 may be penetrated depending on the forming method. A conductive material may be used as a material of the through-via 260, and an insulative barrier layer may be additionally disposed on an exterior side of the through-via 260.

The second semiconductor chip 200 may be a memory chip such as a high bandwidth memory (HBM), but is not limited thereto. The first semiconductor chip 100 and the second semiconductor chip 200 may be disposed on the third semiconductor chip 300. The third semiconductor chip 300 may face a second semiconductor chip 200a disposed lowermost among the second semiconductor chip 200. The third semiconductor chip 300 may include a semiconductor substrate 310, a first connection pad 330, a circuit structure 340, a second connection pad 350 and a through-via 360.

The semiconductor substrate 310 may include silicon (Si), and for example, a silicon substrate. Alternatively, the semiconductor substrate 210 may include a semiconductor element or compound such as germanium (Ge), silicon germanium (SiGe), gallium arsenide (GaAs), silicon carbide (SiC), indium arsenide (InAs).

The first connection pad 330 and the second connection pad 350 are components for electrically connecting the third semiconductor chip 300 to another component, respectively, and may be formed of a conductive material such as copper (Cu) and aluminum (Al). For example, the first connection pad 330 may connect the third semiconductor chip 300 to a substrate (not shown) such as a main substrate and an interposer substrate on which the semiconductor package 1000A is mounted, and the second connection pad 350 may electrically connect the third semiconductor chip 300 to the second semiconductor chip 200a.

The first connection pad 330 and the second connection pad 350 may be disposed on the first surface and the second surface of the third semiconductor chip 300, respectively, and may be electrically connected to each other through the through-via 360. The circuit structure 340 may include a plurality of individual devices (e.g., transistors), internal circuits, interlayer insulating layers, or the like formed through a front end of line (FEOL) process and a back end of line (BEOL) process.

The through-via 360 may penetrate the semiconductor substrate 310 to may electrically connect the first connection pad 330 and the second connection pad 350, and may also be electrically connected to the circuit structure 340. In addition, the through-via 360 may electrically connect the third semiconductor chip 300 to the second semiconductor chip 200a. As a forming method of the through-via 360, via first, via middle, and via last methods may be used without limitation, and all or some of the circuit structure 340 may be penetrated depending on the forming method. A conductive material may be used as a material of the through-via 360, and an insulative barrier layer may be additionally disposed on an exterior side of the through-via 360.

The third semiconductor chip 300 may be a buffer chip for forming a high bandwidth memory (HBM) package, but is not limited thereto. The molding material 10 may be disposed on the first semiconductor chip 100 to mold the second semiconductor chip 200 and the third semiconductor chip 300. If necessary, the molding material 10 may mold the first semiconductor chip 100 together with the second semiconductor chip 200 and the third semiconductor chip 300.

The semiconductor chips 100, 200, and 300 may be electrically connected to each other through conductive bumps b1 and b2 located between their connection pads. First conductive bumps b1 may be disposed on the connection pad 130 of the first semiconductor chip 100 and electrically connect to the connection pad 130 to a second connection pad 260 of the second semiconductor chip 200c. Second conductive bumps b2 may be disposed on the first connection pad 230 of the second semiconductor chip 200 each, and may electrically connect the first connection pad 230 to the second connection pad 250 of another second semiconductor chip 200 or the second connection pad 350 of the third semiconductor chip 300. The conductive bumps b1 and b2 may be, for example, micro solder ball, and may be covered with underfill resin uf.

However, the semiconductor chips 100, 200, and 300 may be electrically connected to each other by hybrid bonding in which respective connection pads are bonded by directly contacting each other. In addition, the second conductive bump b2 for electrically connecting the semiconductor package 1000A to another component such as a substrate on which the semiconductor package 1000A is mounted may be additionally disposed on the first connection pad 330 of the third semiconductor chip 300.

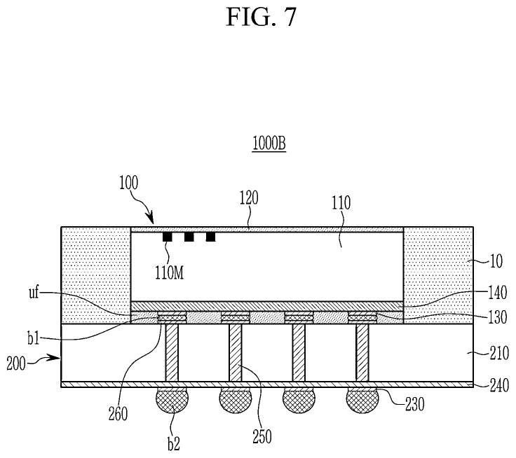

FIG. 7 is a cross-sectional view of another exemplary semiconductor package including a semiconductor chip having an identification mark according to the present disclosure. Referring to the drawings, a semiconductor package 1000B may include the first semiconductor chip 100, and the molding material 10 disposed on the first semiconductor chip 100 and the second semiconductor chip 200 disposed on the first semiconductor chip 100 to mold the second semiconductor chip 200.

In addition, the semiconductor package 1000B may further include the first conductive bump b1 disposed on the connection pad 130 of the first semiconductor chip 100 to electrically connect the connection pad 130 to the second connection pad 250 of the second semiconductor chip 200 and the second conductive bump b2 disposed on the first connection pad 230 of the second semiconductor chip 200. Because the description of other components is the same as that specifically described in the description of the semiconductor package 1000A according to an embodiment of the present disclosure, detailed description of these components will be omitted.

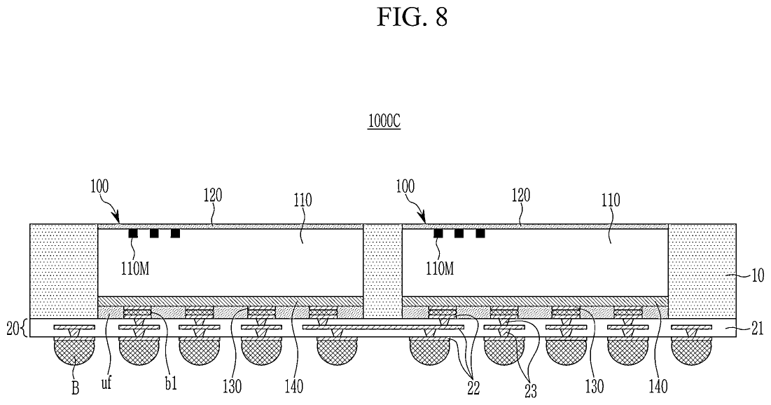

FIG. 8 is a cross-sectional view of a still another exemplary semiconductor package including a semiconductor chip having an identification mark according to the present disclosure. Referring to the drawings, a semiconductor package 1000C may include the first surface of a substrate 20, one or more first semiconductor chips 100 disposed on the substrate, the second surface of the molding material 10 disposed on the first surface of the substrate 20 to mold the first semiconductor chip 100, and a conductive bump B disposed on the substrate 20. The substrate 20 may include an insulation layer 21, one or more wire layers 22, and vias 23 electrically connecting the wire layers 22 disposed on different layers. The substrate 20 may be an interposer substrate that interconnect the one or more first semiconductor chips 100.

The number of the one or more first semiconductor chips 100 is not limited to that shown in the drawings, and may be a single first semiconductor chip 100 or a plurality of first semiconductor chips 100 disposed side by side. The plurality of first semiconductor chips 100 may perform the same function, and may perform different functions. For example, the plurality of first semiconductor chips 100 may be a logic chip, a memory chip, or a controller chip, respectively.

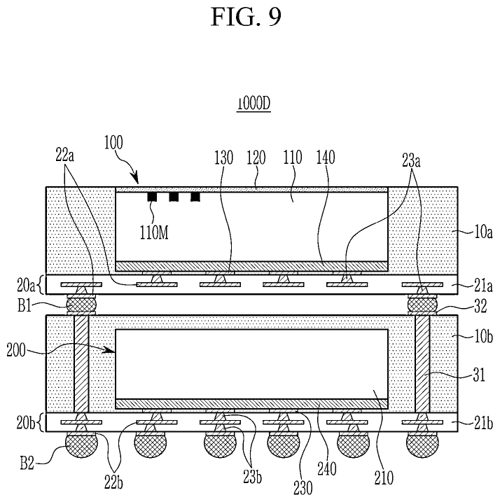

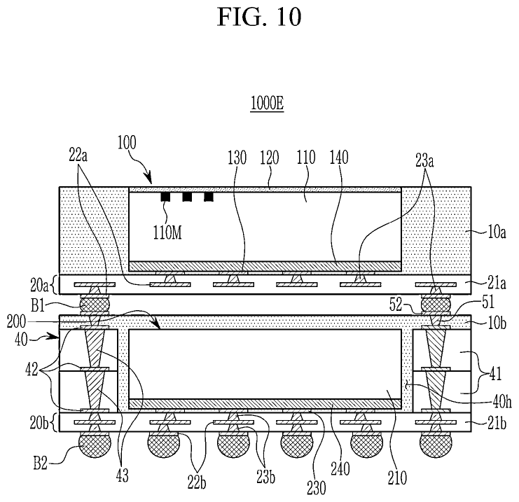

The conductive bump b1 for electrically connecting the first semiconductor chip 100 and the substrate 20 may be disposed between the connection pad 130 of the first semiconductor chip 100 and the wire layer 22 of the substrate 20. As described above, the conductive bump b1 may be covered with the underfill resin uf. However, the connection pad 130 of the first semiconductor chip 100 may directly contact the via 23 of the substrate 20. Such an embodiment is illustrated in FIG. 9 and FIG. 10. Because the description of other components is the same as that specifically described in the description of the semiconductor package 1000A according to an embodiment of the present disclosure, detailed description of these components will be omitted.

FIG. 9 is a cross-sectional view of a still another exemplary semiconductor package including a semiconductor chip having an identification mark according to the present disclosure. Referring to the drawings, a semiconductor package 1000D may include a first substrate 20a, the first semiconductor chip 100 disposed on the first surface of the first substrate 20a, a first molding material 10 disposed on the first surface of the first substrate 20a to mold the first semiconductor chip 100, a second substrate 20b, the second semiconductor chip 200 disposed on the first surface of the second substrate 20b, a second molding material 10 disposed on the first surface of the second substrate 20b to mold the second semiconductor chip 200, a conductive post 31 penetrating the second molding material 10, a first conductive bump B1 disposed on the second surface of the first substrate 20a to electrically connect the conductive post 31 and the first substrate 20a, and a second conductive bump B2 disposed on the second surface of the second substrate 20b.

The first substrate 20a and the second substrate 20b may include respective insulation layers 21a and 21b, one or more wire layers 22a and 22b, and vias 23a and 23b electrically connecting the wire layers 22a and 22b disposed on different layers. The connection pad 130 of the first semiconductor chip 100 may be connected to by direct contact with the first substrate 20a, and/or the connection pad 230 of the second semiconductor chip 200 may be connected to by direct contact with the via 23b of the second substrate 20b. However, as in the case of FIG. 8, the connection pad 130 of the first semiconductor chip 100 connected to a wire layer 22a of the first substrate 20a through a conductive bump, and/or the connection pad 230 of the second semiconductor chip 200 connected to a wire layer 22b of the second substrate 20b through a conductive bump.

The conductive post 31 may electrically connect the second substrate 20b and the first substrate 20a together with the first conductive bump B1. The conductive post 31 may be, for example, a copper (Cu) post. In addition, a post pad 32 for electrically connecting the conductive post 31 to the first conductive bump B1 may be disposed on a second molding material 10b. Because the description of other components is the same as that specifically described in the description of the semiconductor package 1000A according to an embodiment of the present disclosure, detailed description of these components will be omitted.

FIG. 10 is a cross-sectional view of a still another exemplary semiconductor package including a semiconductor chip having an identification mark according to the present disclosure. Referring to the drawings, when compared to the semiconductor package 1000D, the first substrate 20a and the second substrate 20b of a semiconductor package 1000E may be electrically connected to each other through a support substrate 40 instead of the conductive post. The support substrate 40 may have a through-hole 40h in which the second semiconductor chip 200 is disposed, and may include an insulation layer 41, a wire layer 42, and a via 43.

In addition, the semiconductor package 1000E may further include a connection via 51 and a via pad 52 for electrically connecting the support substrate 40 and the first substrate 20a. The connection via 51 may penetrate the second molding material 10 and electrically connect the via pad 52 and the wire layer 42 of the support substrate 40. In addition, the via pad 52 may electrically connect the connection via 51 to the first substrate 20a together with the first conductive bump B1. Because the description of other components is the same as that specifically described in the description of the semiconductor packages 1000A and 1000D according to an embodiment of the present disclosure, detailed description of these components will be omitted.

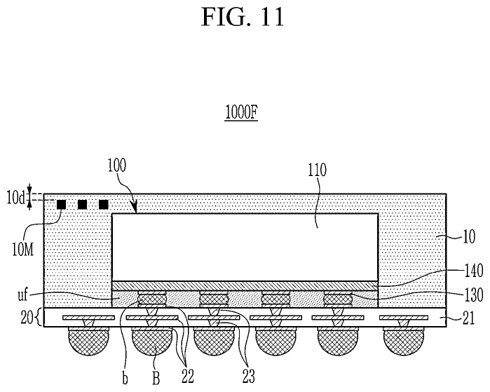

FIG. 11 is a cross-sectional view of an exemplary semiconductor package including a molding material having an identification mark of the present disclosure. Referring to the drawings, a semiconductor package 1000F may include the semiconductor chip 100, the molding material 10 having an identification mark 10M located inward from a surface, and the substrate 20. The semiconductor chip 100 may include the semiconductor substrate 110, the connection pad 130 and the circuit structure 140. In the semiconductor package 1000F, the identification mark 10M may not be formed in the semiconductor chip 100 but in the molding material 10, and accordingly, the semiconductor chip 100 may not include the identification mark 110M and the light transmitting layer 120. However, when needed, the identification mark 110M may also be formed in the semiconductor chip 100, and in this case, the semiconductor chip 100 may include the identification mark 110M and the light transmitting layer 120. The molding material 10 may be disposed on the substrate 20, to mold the semiconductor chip 100. The molding material 10 may be an epoxy mold compound EMC, but is not limited thereto.

The identification mark 10M may be located inside from the surface of the molding material 10. In the present disclosure, the identification mark 10M may be formed inside from (not on) the surface of the molding material 10 by adjusting processing position and wavelength of the laser, and the problem of product contamination due to dust generated during laser processing may be prevented. If necessary, by adjusting the processing position and wavelength of the laser, an identification mark may be formed to be located inside from the surface of the semiconductor substrate 110.

In order to implement the present disclosure, the identification mark 10M may be formed inside the molding material 10, by setting a focus point of the processing laser to be inside the molding material 10 by using a surface sensing laser for sensing the surface of the molding material 10 and a thickness sensing laser for sensing a thickness through a depth from a surface, and by processing the molding material 10 with laser by using laser of a wavelength range to have an appropriate transmittance and absorption rate for the molding material 10.

As the surface sensing laser and the thickness sensing laser, an SLD laser (e.g., wavelength range of 805 nm to 835 nm) for which the molding material 10 has a high transmittance may be used, and the surface and thickness of the molding material 10 may be sensed by using the refractive index (about 1.5 in the case of EMC) of the molding material 10. Based on the sensed surface and thickness of the processing object, the laser processing position of the processing laser may be adjusted to be inside the molding material 10. The laser may form the identification mark 10M by processing the molding material 10, for example, at a wavelength of 350 nm to 800 nm.

The light transmittance of the molding material 10 with respect to a light having a wavelength range 350 nm or more and 800 nm or less may be 70% or more and 90% or less. When the light transmittance of the molding material 10 is above 90%, the processing of the molding material 10 may be difficult, and when it is less than 70%, the processing may be performed on a surface rather than inside of the molding material. From a similar perspective, the light absorption rate of the molding material 10 with respect to the light having a wavelength range 350 nm or more and 800 nm or less may be 10% or more 30% or less.

The identification mark 10M may be located at a depth of 7 μm or more and 50 μm or less from the surface of the molding material 10. Therefore, a depth 10d of the identification mark 10M from the surface of the molding material 10 may be 7 μm or more and 50 μm or less. When the identification mark 10M is located at a depth of above 50 μm from the surface of the molding material 10, it may be difficult to secure visibility of the identification mark 10M. Because the description of other components is the same as that specifically described in the description of the semiconductor package 1000A according to an embodiment of the present disclosure, detailed description of these components will be omitted.

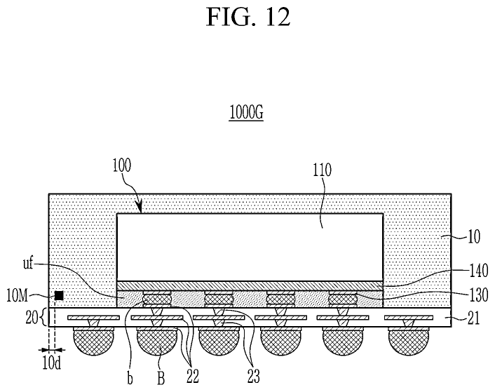

FIG. 12 is a cross-sectional view of another exemplary semiconductor package including a molding material having an identification mark of the present disclosure. Referring to the drawings, in a semiconductor package 1000G, the identification mark 10M may be formed on a side the surface of the molding material 10, when compared to the semiconductor package 1000F. Because the description of other components is the same as that specifically described in the description of the semiconductor packages 1000A and 1000F according to an embodiment of the present disclosure, detailed description of these components will be omitted.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims. Embodiments of the present disclosure may not be independent from each other and may be implemented in a combination with each other unless there is a particular conflict. Accordingly, the content described in the description of one embodiment of the present disclosure may be equally applied to other embodiments even if it is not explicitly described in the description of the other embodiments of the present disclosure.

What is claimed is:

1. A semiconductor chip, comprising:
a semiconductor substrate having an identification mark extending adjacent a first surface thereof;
a light transmitting layer, which extends on the first surface of the semiconductor substrate and covers the identification mark; and
a connection pad extending on a second surface of the semiconductor substrate, which is opposite the first surface of the semiconductor substrate.

2. The semiconductor chip of claim 1, wherein a light absorption rate of the light transmitting layer with respect to light having a wavelength in a range from 355 nm to 980 nm is less than 15%.

3. The semiconductor chip of claim 1, wherein light transmittance of the light transmitting layer with respect to light having a wavelength in a range from 355 nm to 980 nm is 90% or more.

4. The semiconductor chip of claim 1, wherein the light transmitting layer comprises silicon oxide.

5. The semiconductor chip of claim 4, wherein the light transmitting layer further comprises at least one of titanium dioxide (TiO₂) and gold (Au) nanoparticles therein.

6. The semiconductor chip of claim 1, wherein a light absorption rate of the light transmitting layer with respect to a light having a wavelength in a range from 355 nm to 980 nm is less than 1.5%.

7. The semiconductor chip of claim 1, wherein a light absorption rate of the semiconductor substrate with respect to a light having a wavelength in a range from 355 nm to 980 nm is at least 15%.

8. The semiconductor chip of claim 1, wherein a region where the identification mark is located within the semiconductor substrate includes amorphous silicon, and another region outside where the identification mark is located includes single crystalline silicon.

9. The semiconductor chip of claim 1, wherein thickness of the light transmitting layer is in a range from 7 μm to 70 μm.

10. The semiconductor chip of claim 1, wherein the light transmitting layer is transparent or translucent.

11. A semiconductor package, comprising:
a first semiconductor chip including:
a semiconductor substrate having an identification mark therein, which extends adjacent a first surface of the semiconductor substrate; and
a light transmitting layer that extends on the first surface of the semiconductor substrate and covers the identification mark; and
a molding material molding to the first semiconductor chip;
wherein the light transmitting layer is exposed to a first surface of the molding material.

12. The package of claim 11, wherein a light absorption rate of the light transmitting layer with respect to light having a wavelength in a range from 355 nm to 980 nm is less than 15%.

13. The package of claim 11, wherein a light transmittance of the light transmitting layer with respect to light having a wavelength in a range from 355 nm to 980 nm is 90% or more.

14. The package of claim 11, wherein the semiconductor package further includes a through-via therein, and one or more second semiconductor chips electrically connected to the first semiconductor chip through the through-via; and wherein the first semiconductor chip extends on the second semiconductor chip.

15. The package of claim 14, wherein the second semiconductor chip is a memory chip.

16. A semiconductor package, comprising:
a semiconductor chip; and
a molding material that molds to the semiconductor chip and has an identification mark therein, which is located inside from a surface of the molding material.

17. The package of claim 16, wherein a light transmittance of the molding material with respect to light having a wavelength in a range from 350 nm to 800 nm is in a range from 70% to 90%.

18. The package of claim 16, wherein a light absorption rate of the molding material with respect to light having a wavelength in a range from 350 nm to 800 nm is in a range from 10% to 30%.

19. The package of claim 16, wherein the identification mark is located at a depth in a range from 7 μm to 50 μm relative to the surface of the molding material.

20. The package of claim 16, wherein the molding material is an epoxy mold compound (EMC).
